(19) United States
(12) Patent Application Publication
(10) Pub. No.: US 2025/0022502 A1
(43) Pub. Date: Jan. 16, 2025

(54) SEMICONDUCTOR MEMORY DEVICE CAPABLE OF CONTROLLING ROW HAMMERING AND METHOD OF DRIVING THE SAME

(71) Applicant: SK hynix Inc., Gyeonggi-do (KR)

(72) Inventor: Seok Young KANG, Gyeonggi-do (KR)

(21) Appl. No.: 18/533,172

(22) Filed: Dec. 8, 2023

(30) Foreign Application Priority Data
Jul. 13, 2023 (KR) 10-2023-0091152

(51) Int. Cl. G11C 11/408

(52) U.S. Cl. CPC G11C 11/4085

(57) ABSTRACT

A semiconductor memory device may include a memory cell array and a row hammer control block. The memory cell array may include word lines, bit lines crossed with the word lines and memory cells arranged between the word lines and the bit lines. The row hammer control block controls a voltage of a victim word line adjacent to a selected word line among the word lines, and includes a victim word line determination circuit and a victim voltage output circuit. The victim word line determination circuit receives address information of the selected word line as address information of an aggressor word line to determine at least one of the word lines adjacent to the aggressor word line. The victim voltage output circuit may temporarily output a victim voltage different from an off voltage, which is applied to non-selected word lines during a falling section of the aggressor word line.

### CROSS-REFERENCES TO RELATED APPLICATION

The present application claims priority under 35 U.S.C. § 119(a) to Korean application number 10-2023-0091152, filed on Jul. 13, 2023, which is incorporated herein by reference in its entirety.

### BACKGROUND

### 1. Technical Field

Various embodiments of the present disclosure generally relate to a semiconductor memory device and a method of driving the same. More particularly, various embodiments of the present disclosure relate to a semiconductor memory device capable of controlling row hammering and to a method of driving the semiconductor memory device.

### 2. Related Art

Increasing the integration degree (also known as integration density) of a semiconductor memory device results in reduced pitch between word lines. Integration degree or density refers to how densely the various components such as transistors, logic gates, and memory cells are integrated onto the semiconductor substrate. The higher the integration degree the lesser the distance between conductive lines such as word-lines becomes. Thus, when an adjacent word line is selected, a phenomenon known as row hammer (or row hammering) may be observed that may change data characteristics of a memory cell connected to the adjacent word line.

Row hammer presents security and reliability issues and, hence, there is a need for new, improved technologies for addressing row hammer for the more advanced, higher integration degree semiconductor memory devices.

### SUMMARY

Various embodiments of the present disclosure provide a semiconductor memory device having improved data reliability, and also a method of driving the semiconductor memory device.

According to embodiments of the present disclosure, a semiconductor memory device is provided which includes a memory cell array and a row hammer control block. The memory cell array may include a plurality of word lines, a plurality of bit lines crossed with the word lines and a plurality of memory cells arranged at crossed points between the word lines and the bit lines. The row hammer control block may control a voltage of a victim word line adjacent to a selected word line among the word lines. The row hammer control block may include a victim word line determination circuit and a victim voltage output circuit. The victim word line determination circuit may receive address information of the selected word line as address information of an aggressor word line to determine at least one of the word lines adjacent to the aggressor word line as the victim word line. The victim voltage output circuit may temporarily output a victim voltage different from an off voltage, which may be applied to non-selected word lines during a falling section of the aggressor word line.

According to embodiments of the present disclosure, there is provided a method of driving the semiconductor memory device which includes applying a driving voltage to a selected word line among a plurality of word lines and an off voltage to remaining non-selected word lines. The method further includes applying a victim voltage different from the off voltage to a word line nearest to the selected word line during a falling section where a voltage of the selected word line is changed from the driving voltage to the off voltage.

According to embodiments of the present disclosure, a method of driving a semiconductor memory device may include setting a victim word line from address information of an aggressor word line and applying a victim voltage different from an off voltage to the victim word line during a falling section of the aggressor word line.

According to embodiments of the present disclosure, there is provided a semiconductor memory device which includes an active region, first and second gates, a drain, a first source and a second source.

The first and second gates may be arranged on the active region. The drain may be formed in the active region between the first and second gates. The drain may be electrically connected to a non-selected bit line. The first source may be formed in the active region outside the first gate. The first source may be electrically connected to a first storage capacitor. The second source may be formed in the active region outside the second gate. The second source may be electrically connected to a second storage capacitor. The first gate may be connected to a selected word line. The second gate may be connected to a non-selected word line.

When the selected word line is disabled, the second gate receiving an off voltage may temporarily receive a victim voltage different from the off voltage.

According to embodiments of the present disclosure, the victim voltage, which may be different from the off voltage, may be temporarily applied to the victim word line during the falling section of the selected word line, i.e., the falling section of the aggressor word line. Thus, negative charges trapped in a portion, which may act as a pass gate of the selected word line, may be moved to an adjacent memory cell to prevent the row hammering, thereby improving the data reliability.

### BRIEF DESCRIPTION OF THE DRAWINGS

The above and another aspects, features, and advantages of the subject matter of the present disclosure will be better understood from the following detailed description in conjunction with the accompanying drawings, in which:

FIG. 1 is a simplified block diagram illustrating a semiconductor memory device in accordance with embodiments of the present disclosure;

FIG. 2 is a plan view schematic illustrating a memory bank in accordance with embodiments of the present disclosure;

FIG. 3 is an enlarged plan view schematic of a portion “A” in FIG. 2;

FIG. 4 is a simplified block diagram illustrating a row hammer control block in FIG. 1;

FIG. 5 is timing chart illustrating voltages applied to an aggressor word line, a victim word line and a non-selected word line in accordance with embodiments of the present disclosure;

FIG. 6 is a flow chart of a method of controlling row hammering in a semiconductor memory device in accordance with embodiments of the present disclosure; and

FIG. 7 is a cross-sectional view taken along a line VII-VII′ in FIG. 3 for describing an operation for mitigating row hammering in accordance with embodiments of the present disclosure.

### DETAILED DESCRIPTION

Various embodiments of the present disclosure will be described in greater detail with reference to the accompanying drawings. The drawings are schematic illustrations of various embodiments and intermediate structures. As such, variations from the configurations and shapes of the illustrations as a result, for example, of manufacturing techniques and/or tolerances, are to be expected. Thus, the described embodiments should not be construed as being limited to the particular configurations and shapes illustrated herein but may include deviations in configurations and shapes which do not depart from the technical concepts and scope of the present disclosure as defined in the appended claims.

Embodiments of the present invention are described herein with reference to cross-section and/or plan illustrations of idealized embodiments of the present disclosure. However, embodiments of the present disclosure should not be construed as limiting the inventive concept. Although a few embodiments of the present disclosure will be shown and described, it will be appreciated by those of ordinary skill in the art that changes may be made in these embodiments without departing from the principles and technical concepts of the present disclosure.

As used herein, a “memory device” refers to microelectronic devices exhibiting memory functionality, but not necessarily limited to memory functionality. Stated another way, and by way of non-limiting example only, the term “memory device” includes not only conventional memory devices (e.g., conventional volatile memory; conventional non-volatile memory), but may also include an application specific integrated circuit (ASIC) (e.g., a system on a chip (SoC)), a microelectronic device combining logic and memory, and a graphics processing unit (GPU) incorporating memory.

As used herein, the term “configured” refers to a size, shape, material composition, orientation, and arrangement of one or more of at least one structure and at least one apparatus facilitating operation of one or more of the structure and the apparatus in a pre-determined way.

As used herein, the terms “vertical,” “longitudinal,” “horizontal,” and “lateral” are in reference to a major plane of a structure and are not necessarily defined by the earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the figures, a “horizontal” or “lateral” direction may be perpendicular to an indicated “Z” axis, and may be parallel to an indicated “X” axis and/or parallel to an indicated “Y” axis; and a “vertical” or “longitudinal” direction may be parallel to an indicated “Z” axis, may be perpendicular to an indicated “X” axis, and may be perpendicular to an indicated “Y” axis.

As used herein, features (e.g., regions, structures, devices) described as “neighboring” one another means and includes features of the disclosed identity (or identities) that are located most proximate (e.g., closest to) one another. Additional features (e.g., additional regions, additional structures, additional devices) not matching the disclosed identity (or identities) of the “neighboring” features may be disposed between the “neighboring” features. Put another way, the “neighboring” features may be positioned directly adjacent to one another, such that no other feature intervenes between the “neighboring” features; or the “neighboring” features may be positioned indirectly adjacent to one another, such that at least one feature having an identity other than that associated with at least one “neighboring” features is positioned between the “neighboring” features. Accordingly, features described as “vertically neighboring” one another means and includes features of the disclosed identity (or identities) that are located most vertically proximate (e.g., vertically closest) to one another. Moreover, features described as “horizontally neighboring” one another means and includes features of the disclosed identity (or identities) that are located most horizontally proximate (e.g., horizontally closest) to one another.

As used herein, spatially relative terms, such as “beneath,” “below,” “lower,” “bottom,” “above,” “upper,” “top,” “front,” “rear,” “left,” “right,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation depicted in the figures. For example, if materials in the figures are inverted, elements described as “below” or “beneath” or “under” or “on bottom of” other elements or features would then be oriented “above” or “on top of” the other elements or features. Thus, the term “below” can encompass both an orientation of above and below, depending on the context in which the term is used, which will be evident to one of ordinary skill in the art. The materials may be otherwise oriented (e.g., rotated 90 degrees, inverted, flipped) and the spatially relative descriptors used herein interpreted accordingly.

As used herein, the singular forms “a,” “an,” and “the” are intended to include the plural forms as well, unless the context clearly indicates otherwise.

As used herein, “and/or” includes any and all combinations of one or more of the associated listed items.

As used herein, it will be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present. Like numbers indicate like elements throughout.

As used herein, the term “substantially” in reference to a given parameter, property, or condition means and includes to a degree that one of ordinary skill in the art would understand that the given parameter, property, or condition is met with a degree of variance, such as within acceptable tolerances. By way of example, depending on the particular parameter, property, or condition that is substantially met, the parameter, property, or condition may be at least 90.0 percent met, at least 95.0 percent met, at least 99.0 percent met, at least 99.9 percent met, or even 100.0 percent met.

A semiconductor memory device of various embodiments may include a plurality of memory cells. The memory cells may store at least one bit information. The memory cells may be defined by word lines and bit lines crossed with each other. The word lines, the bit lines and the memory cells may form a memory bank. The semiconductor memory device may include at least one memory bank. Further, the semiconductor memory device may receive the at least one command signal for instructing operation of the semiconductor memory device. For example, the semiconductor memory device may refresh the at least one word line of the at least one memory bank based on a refresh command.

As is well known, information stored in the semiconductor memory device, particularly, a dynamic random access memory (DRAM) may be decayed in accordance with a time lapse. To preserve the information in the memory cells, the memory cells may perform a refresh operation by a row unit, for example, a word line unit. A voltage for preserving the data information may be re-registered in the word lines during the refresh operation.

A selected word line or an aggressor word line may cause a change of the data information in the memory cell connected to a physically adjacent other word line (hereinafter, referred to as a victim word line).

The semiconductor memory device of various embodiments may identify the aggressor word line and the victim word line. The semiconductor memory device may control a voltage level of the victim word line during a specific section. Thus, the data change of the memory cell connected to the victim word line may be prevented.

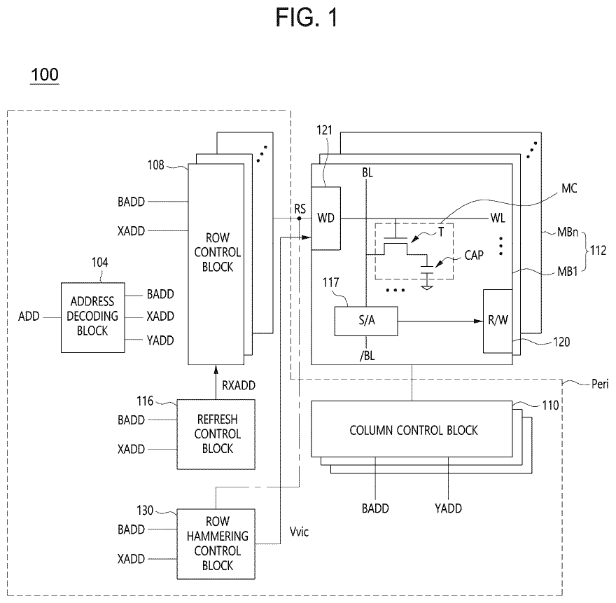

FIG. 1 is a simplified block diagram illustrating a semiconductor memory device in accordance with some embodiments of the present disclosure.

Referring to FIG. 1, a semiconductor memory device 100 may include a memory cell array 112 and a peripheral circuit Peri.

In example embodiments, the memory cell array 112 and the peripheral circuit Peri may be horizontally arranged on one wafer. Alternatively, the memory cell array 112 and the peripheral circuit Peri may be vertically arranged on one wafer. For example, the memory cell array 112 may be arranged over the peripheral circuit Peri. Alternatively, the memory cell array 112 and the peripheral circuit Peri may be integrated in different wafers. The different wafers may then be bonded to each other.

The memory cell array 112 may include a plurality of memory banks MB1˜MBn. Each of the memory banks MB1˜MBn may include a plurality of word lines WL, a plurality of bit lines BL and a plurality of memory cells MC arranged at crossed portions between the word lines WL and the bit lines BL. In some embodiments, the memory banks MB1˜MBn may be integrated in one wafer or a plurality of wafers.

For example, each of the memory cells MC may include a switching transistor T and a storage capacitor CAP. When a word line and a bit line connected to the switching transistor T are selected, the switching transistor T may be enabled. Data may then be stored in or read from the storage capacitor CAP connected to the switching transistor T.

The peripheral circuit Peri may include an address decoding block 104, a row control block 108, a column control block 110, a refresh control block 116 and a row hammer control block 130 (also referred to as row hammering control block).

The address decoding block 104 may receive an address ADD provided from an external device to generate a bank address BADD, a row address XADD and a column address YADD.

The row control block 108 may receive the bank address BADD and the row address XADD to generate a row selection signal Rs. For example, the row selection signal Rs may include at least one signal. The row selection signal Rs may include address information of a selected word line and row enable information for determining an enable time of the selected word line. A word line driver 121, which may be provided to each of the memory banks MB1˜MBn, may select a selected memory bank, or at least one word line WL of a part of the selected memory bank in response to the row selection signal Rs. The part of the selected memory bank may be a sub-bank or a part of the sub-bank.

The column control block 110 may receive the bank address BADD and the column address YADD and may use these for selecting a bit line BL of a selected memory bank among the memory banks MB1 to MBn.

In example embodiments, the row control block 108 and the column control block 110 may correspond to each of the memory banks MB1˜MBn.

The memory cell array 112 may further include a sense amplifier 117 connected to the bit lines BL and /BL. The sense amplifier 117 may detect and amplify data read by the bit line BL or /BI in the form of voltages. The memory cell array 112 may further include a read/write driver 120 electrically connected with the sense amplifier 117. The read/write driver 120 may output the data amplified by the sense amplifier 117 as read data, or provide the sense amplifier 117 with write data provided from the external device.

The semiconductor memory device 100 may further include the refresh control block 116. The refresh control block 116 may generate a refresh address RXADD for refreshing at least one word line WL in accordance with a refresh command. The refresh control block 116 may provide the row control block 108 with the refresh address RXADD.

A refresh operation may prevent loss of data due to charge leakage. For example, the refresh operation may be performed automatically. For example, the memory bank may refresh a selected word line or a selected word line group including word lines in response to the automatic refresh operation. Then, the memory bank may automatically refresh a next word line or a next word line group. The refresh control block 116 may circularly refresh all word lines WL of the memory banks MB1˜MBn within a predetermined time selected to prevent data loss. For example, a typical refresh operation may include 1) selecting a specific row of memory cells, 2) reading the data stored in each memory cell in the selected row, 3) after reading the data, refreshing the data, i.e., rewriting the same data back into the memory cells, 4) repeating the above steps for the next row of memory cells till all memory cells have been refreshed. The refresh process is performed periodically to ensure no loss of data.

The row hammer control block 130 may receive the bank address BADD and the row address XADD to determine a victim word line based on an aggressor word line. The row hammer control block 130 may output a victim voltage Vvic to the victim word line during a specific time. In some embodiments, the victim voltage Vvic may be outputted to the victim word line. Alternatively, the row hammer control block 130 may output an address for instructing the victim word line, or address information to the memory cell array 112. The word line driver 121 of the memory cell array 112 may generate the victim voltage Vvic in response to the address for instructing the victim word line.

Hereinafter, the row hammer control block 130 may be illustrated in detail.

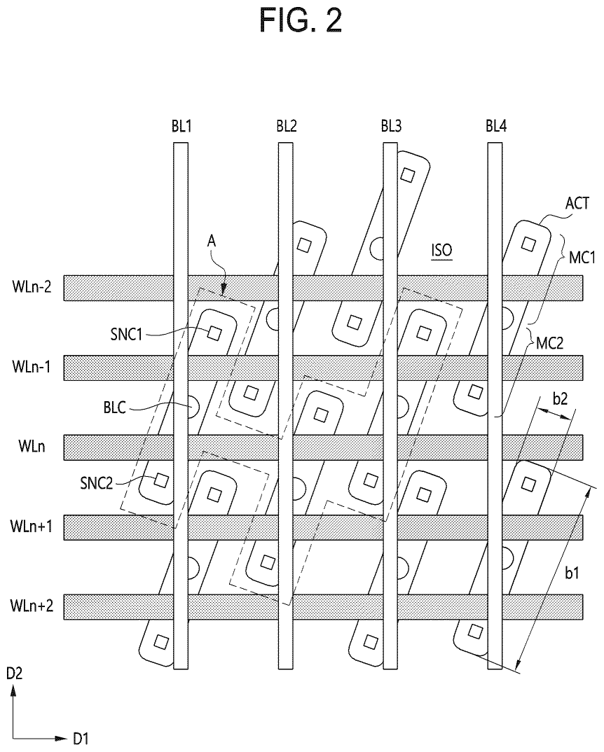

FIG. 2 is a plan view schematic illustrating a memory bank in accordance with some embodiments of the present disclosure.

Referring to FIG. 2, a memory bank MB may include a plurality of word lines WLn−2˜WLn+2, a plurality of bit lines BL1˜BL4 and a plurality of active regions ACT.

The word lines WLn−2˜WLn+2 may extend parallel to each other along a first direction D1. The bit lines BL1˜BL4 may extend parallel to each other along a second direction D2 which may be substantially perpendicular to the first direction D1.

The active regions ACT may be defined at crossed points between the word lines WLn−2˜WLn+2 and the bit lines BL1˜BL4.

Each of the active regions ACT may have a long axis b1 and a short axis b2. The long axis b1 and the short axis b2 of the active regions ACT may be tilted with respect to the word lines WLn−2˜WLn+2 and the bit lines BL1˜BL4.

For example, one active region ACT may overlap with two adjacent word lines. One active region ACT may electrically contact one bit line. Thus, one active region ACT may include one bit line contact BLC and two storage contacts SNC1 and SNC2. As a result, two memory cells MC1 and MC2 may be integrated in one active region ACT.

In some embodiments, to integrate more active regions ACT in a limited memory cell array, the active regions ACT may be arranged in a staggered shape. The active regions ACT may be defined by an isolation region ISO on a semiconductor substrate or a structure on the semiconductor substrate.

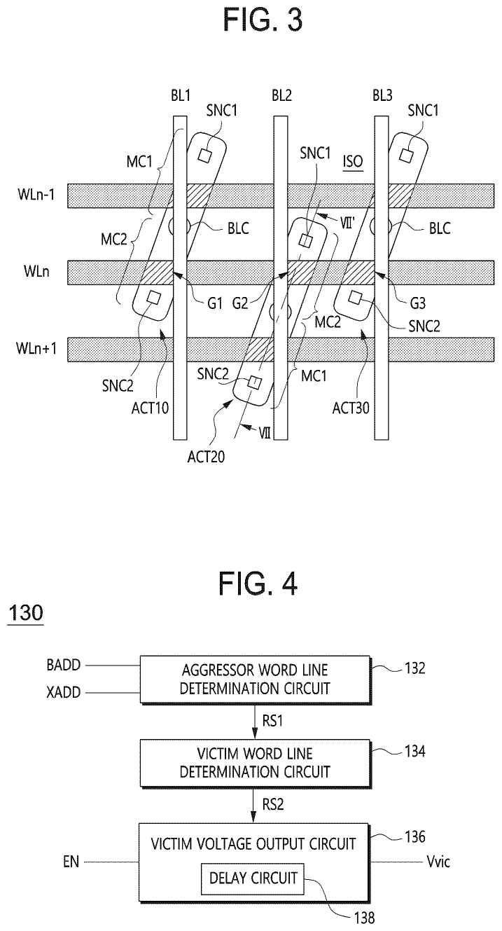

FIG. 3 is an enlarged plan view schematic of a portion “A” shown in FIG. 2.

Referring to FIG. 3, when an nth word line WLn and a first bit line BL1 are selected, a memory operation may be performed on a second memory cell MC2 in a first active region ACT10.

The selected nth word line WLn may receive a logic high level of a driving voltage during an enable section. Remaining non-selected word lines may receive a logic low level of an off voltage. The driving voltage and the off voltage may be provided from the word line driver 121 or a voltage generation circuit in the peripheral circuit Peri.

A first portion G1 of the nth word line WLn overlapping with the first active region ACT10 may be a main gate contributing to a memory operation of the second memory cell MC2 in the first memory region ACT10.

A second portion G2 and a third portion G3 of the nth word line WLn overlapping with a second active region ACT20 and a third active region ACT30, respectively, may be a pass gate not contributing to an actual memory operation. That is, because the second active region ACT20 and the third active region ACT30 may be connected to the non-selected bit lines BL2 and BL3, the second portion G2 and the third portion G3 may not turn-on a switching transistor of a corresponding memory cell. The second portion G2 and the third portion G3 receive the high driving voltage but correspond to gates of non-selected memory cells, that is, the pass gate. Thus, parasitic electric fields may be generated between the pass gate and a storage capacitor adjacent to the pass gate, then charges stored in the storage capacitor may leak.

In some embodiments, the main gate and the pass gate may be defined as a part of the selected word line. As mentioned above, the main gate may correspond to a portion of the word line on the selected memory cell or an active region where the corresponding memory cell may be integrated. The pass gate may correspond to a portion of the word line on the non-selected memory cell or an active region where the corresponding memory cell may be integrated.

Particularly, because the logic high level of the driving voltage may be applied to the second portion G2 of the nth word line WLn, negative charges of capacitors connected to the first storage node contact SNC1 in the second active region ACT20 may be trapped into an interface between the capacitors and the second portion G2 due to Coulomb's law.

When the nth word line WLn is disabled so that the off voltage can be applied to the nth word line WLn, the negative charges trapped in the second portion G2 may not be readily returned to the first storage node SNC1. The negative charges may be floated or moved toward an adjacent memory cell.

Therefore, data information in the first memory cell MC1 of the second active region ACT20 may be decayed. The floated negative charges may act as a generation source of a gate induced drain leakage (GIDL). As mentioned above, this may be the row hammering.

Further, in order to reduce an off current, when a pumping voltage Vpp or Vppw is used as the driving voltage and a negative voltage Vbb or Vbbw is used as the off voltage, the row hammering may be remarkably increased.

In some embodiments, in order to prevent or mitigate the row hammering phenomenon, the selected word line may be set as the aggressor word line. The at least one word line physically adjacent to the aggressor word line may be set as the victim word line. The voltage applied to the victim word line may then be controlled during the specific time to prevent or mitigate the row hammering.

FIG. 4 is a simplified block diagram illustrating a row hammer control block in FIG. 1.

Referring to FIGS. 1 and 4, the row hammer control block 130 may include an aggressor word line determination circuit 132, a victim word line determination circuit 134 and a victim voltage output circuit 136.

The aggressor word line determination circuit 132 may receive the bank address BADD and the row address XADD to generate an aggressor selection signal RS1 for selecting an aggressor word line. In some embodiments, the aggressor word line may be a selected word line of the memory cell array 112.

The victim word line determination circuit 134 may receive the aggressor selection signal RS1 to determine at least one of a selected word line and adjacent word lines as a victim word line. The victim word line determination circuit 134 may generate a victim word line selection signal RS2 for selecting the victim word line.

The victim voltage output circuit 136 may receive the victim word line selection signal RS2 and enable information of the row selection signal to output the victim voltage Vvic to the victim word line during a falling edge section of the aggressor word line.

The victim voltage output circuit 136 may include a delay circuit 138 to output the victim voltage Vvic from a falling edge of the aggressor word line during a set delay time of the delay circuit 138. After the delay time, the victim voltage output circuit 136 may be disabled and the victim word line may receive the off voltage.

In some embodiments, the victim voltage Vvic may have a voltage level different from a voltage level of the off voltage. For example, the victim voltage Vvic may include a negative voltage Vbb or Vbbw different from the off voltage, but not limited thereto.

Alternatively, the row hammer control block 130 may not include the aggressor word line determination circuit 132. In this case, the row hammer control block 130 may directly receive the word line selection signal Rs outputted from the row control block 108 as the aggressor selection signal RS1.

In some embodiments, the row hammer control block 130 may be separated from the row control block 108 and refresh control block 116. Alternatively, the row hammer control block 130 may be a part of the row control block 108 or a part of the refresh control block 116.

Further, the row hammer control block 130 may be provided to the peripheral circuit Peri. Alternatively, the row hammer control block 130 may be provided in the memory cell array 112.

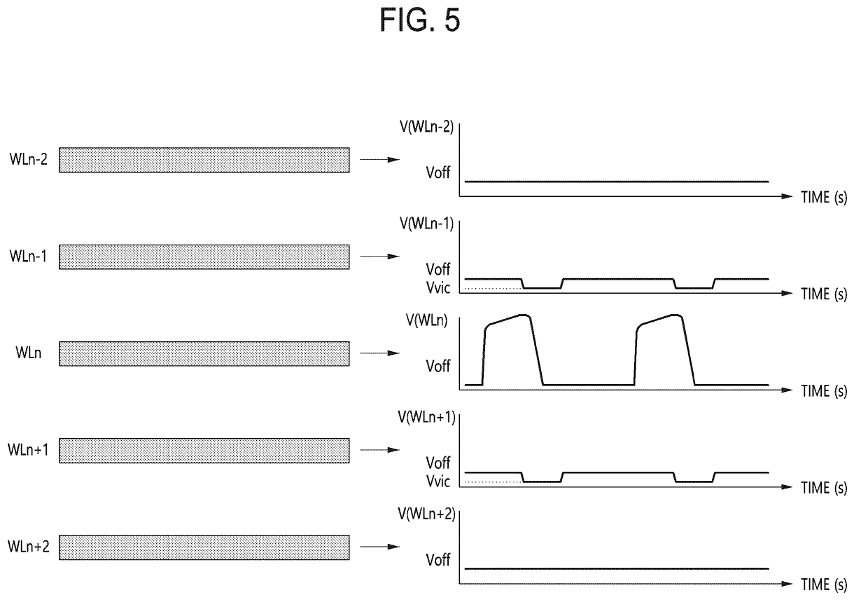

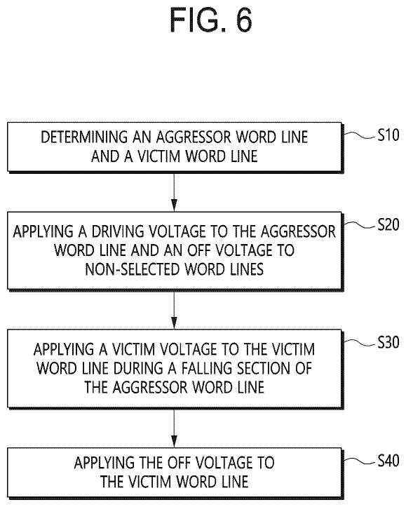

FIG. 5 is timing chart illustrating voltages applied to an aggressor word line, a victim word line and a non-selected word line in accordance with embodiments of the present disclosure and FIG. 6 is a flow chart of a method of controlling a row hammering in a semiconductor memory device in accordance with embodiments of the present disclosure.

Referring to FIGS. 5 and 6, when the nth word line WLn is selected, in operation S10, the row hammer control block 130 may determine the nth word line WLn as the aggressor word line AWL. The row hammer control block 130 may determine at least one of the adjacent word lines WLn±1˜WLn±a (a is a natural number) to the aggressor word line AWL as the victim word line VWL. The adjacent word lines WLn±1˜WLn±a may be an option randomly set by a designer based on an influence of the row hammering through a test.

In operation S20, the driving voltage Von may be applied to the selected nth word line WLn, i.e., the aggressor word line AWL. The off voltage Voff may be applied to the non-selection word lines WLn±1˜WLn±a. The driving voltage may include a logic high voltage, for example, the pumping voltage Vpp or Vppw. The off voltage Voff may include a logic low voltage, for example, a ground voltage.

The process in operation S20 may be substantially the same as a process for driving a normal word line. Thus, the process in operation S20 may be performed by the row control block 108 and the word line driver 121.

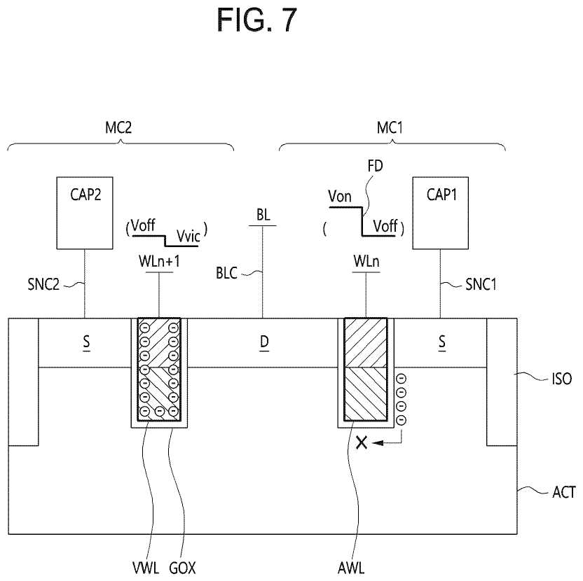

In operation S30, when the nth word line WLn as the aggressor word line AWL is disabled, the victim voltage Vvic may be applied to the victim word line VWL during the falling section FD of the aggressor word line AWL (Please see FIG. 7).

The victim voltage Vvic may have a voltage level different from a voltage level of the off voltage Voff. In some embodiments, when the off voltage Voff includes the ground voltage, for example, about 0V, the victim voltage Vvic may include the negative voltage Vbb or Vbbw within a range of −0.1V to about −0.03V.

Further, the falling section may be controlled by a delay value of the delay circuit 138 in the victim voltage output circuit 136. The delay value may be randomly set by considering a level of the row hammering in the memory device. The process in operation S30 may be performed by the row hammer control block 130.

In operation S40, when the nth word line WLn is completely disabled, the off voltage Voff may be applied to the victim word line VWL.

An operation for mitigating, or preventing the row hammering in accordance with voltage applying types of the victim word line may be illustrated with reference to FIG. 7.

FIG. 7 is a cross-sectional view taken along a line VII-VII′ in FIG. 3 for describing an operation for mitigating, or preventing a row hammering in accordance with embodiments of the present disclosure. FIG. 7 may show an active region ACT20 including a pass gate (as shown in FIG. 3).

Referring to FIG. 3 and FIG. 7, the active region ACT20 may be defined on the semiconductor substrate or a structure on the semiconductor substrate by an isolation layer ISO.

The selected aggressor word line AWL and the victim word line VWL may be arranged on the active region ACT20. The aggressor word line AWL may correspond to the second portion G2 of the nth word line WLn in FIG. 3. The victim word line VWL may correspond to a (n+1)th word line WLn+1. When the active region in FIG. 7 shows the third active region ACT30 in FIG. 3, the victim word line VWL may correspond to a (n−1)th word line.

The aggressor word line AWL and the victim word line VWL may have a buried gate structure, but are not limited thereto. A gate insulation layer Gox may be interposed between the aggressor word line AWL and the active region ACT20 and between the victim word line VWL and the active region ACT20.

N type impurities n+ may be implanted into the active regions ACT20 at both sides of the aggressor word line AWL and the victim word line VWL to form a drain D and a source S. The drain D may be positioned in the active region ACT20 between the aggressor word line AWL and the victim word line VWL. The source S may be positioned in the active region ACT20 outside the aggressor word line AWL and the victim word line VWL.

The drain D may be connected with a non-selected bit line BL2 through a bit lint contact BLC. The source S adjacent to the aggressor word line AWL may be connected to a first storage capacitor CAP1 through the first storage node contact SNC1. The source S adjacent to the victim word line VWL may be connected to a second storage capacitor CAP2 through the second storage node contact SNC2.

For example, when the driving voltage Von is applied to the nth word line WLn, the negative charges of the first storage capacitor CAP1 may be trapped on a surface of the aggressor word line AWL by an influence of an electric field generated from the driving voltage Von.

When the aggressor word line AWL is disabled to the off voltage Voff having the logic low level, the trapped negative charges around the aggressor word line AWL may be free from the influence of the electric field.

During the falling section of the aggressor word line AWL (as shown in FIG. 7), the victim voltage Vvic different from the off voltage Voff may be temporarily applied to the victim word line VWL. Thus, the voltage level of the victim word line VWL may be temporarily lower than the voltage level of the aggressor word line AWL. As a result, the negative charges may be distributed in the victim word line VWL by the victim voltage Vvic.

Therefore, a repulsive force may be generated between the negative charges trapped in the victim word line VWL and the negative charges concentrated on the aggressor word line AWL so that the negative charges decayed from the first storage capacitor CAP1 may be returned to the first storage capacitor, and are not moved toward the victim word line VWL, thereby mitigating, or preventing the row hammering.

According to embodiments, the victim voltage that is lower than the off voltage may be temporarily applied to the victim word line during the falling section of the aggressor word line. Thus, the negative charges trapped in the portion as the pass gate of the selected word line may be moved to the adjacent memory cell to prevent or mitigate the row hammering, thereby improving the data reliability.

The above described embodiments of the present disclosure are intended to illustrate and not to limit the present disclosure. Various alternatives and equivalents are possible. The invention is not limited by the embodiments described herein. Nor is the invention limited to any specific type of semiconductor device. Other additions, subtractions, or modifications are apparent in view of the present disclosure and are intended to fall within the scope of the appended claims. Furthermore, the embodiments may be combined to form additional embodiments.

1-6. (canceled)

7. A method of driving a semiconductor memory device, the method comprising:
applying a driving voltage to a selected word line among a plurality of word lines;
applying an off voltage to remaining non-selected word lines; and
applying a victim voltage, which is different from the off voltage, to a word line adjacent to the selected word line among the non-selected word lines during a falling section where a voltage of the selected word line is transited from the driving voltage to the off voltage.

8. The method of claim 7, wherein the driving voltage comprises a voltage having a logic high level, the off voltage comprises a ground voltage and the victim voltage has a voltage level lower than a voltage level of the off voltage.

9. The method of claim 7, wherein the selected word line comprises an nth word line among the word lines, and the victim word line comprises at least one of a (n±1)th word lines to a (n±a)th word line, where a is a natural number, among the word lines.

10. The method of claim 7, wherein the falling section is delayed from a falling edge where the driving voltage is transited to the off voltage.

11. A method of driving a semiconductor memory device, the method comprising:
setting a victim word line from address information of an aggressor word line; and
applying a victim voltage, which is different from an off voltage, to the victim word line during a falling section of the aggressor word line.

12. The method of claim 11, wherein the address information of the aggressor word line comprises address information of a selected word line among the word lines.

13. The method of claim 12, wherein the victim word line comprises at least one of word lines adjacent to the selected word line.

14. The method of claim 12, further comprising:
applying a driving voltage having a logic high level to the aggressor word line during an enable section of the aggressor word line; and
applying the off voltage having a logic low level to a non-selected word line among the word lines.

15-17. (canceled)

18. A method of driving a semiconductor memory device, the method comprising:
selecting a word line among a plurality of word lines of a memory bank;
applying a driving voltage to the selected word line;
applying an off voltage to remaining non-selected word lines of the memory bank; and
applying a victim voltage, which is different from the off voltage, to a word line that is disposed adjacent to the selected word line among the non-selected word lines when the voltage of the selected word line is falling from the driving voltage to the off voltage.
